(19) United States
(12) Patent Application Publication
(10) Pub. No.: US 2025/0246818 A1
(43) Pub. Date: Jul. 31, 2025

(54) MICRO-ACOUSTIC FILTENNA

(71) Applicant: QUALCOMM Incorporated, San Diego, CA (US)

(72) Inventors: Edgar Konrad SCHMIDHAMMER, Stein an der Traun (DE); Manfred STADLER, Seiersberg (AT); Juha Sakari ELLA, Turku (FI)

(21) Appl. No.: 18/890,565

(22) Filed: Sep. 19, 2024

Related U.S. Application Data
(60) Provisional application No. 63/624,879, filed on Jan. 25, 2024.

(51) Int. Cl. H01Q 15/00; H01Q 3/26; H03H 9/64

(52) U.S. Cl. CPC H01Q 15/0013; H01Q 3/2688; H03H 9/6483

(57) ABSTRACT

A filtenna using micro-acoustic resonators is provided. One example filtenna generally includes an antenna configured to have a first resonance frequency associated with electromagnetic oscillations of the antenna and one or more acoustic resonators coupled to the antenna, a first acoustic resonator in the one or more acoustic resonators configured to have a second resonance frequency associated with acoustic oscillations of the first acoustic resonator. The filtenna is configured to have a filter transfer function based at least in part on the first resonance frequency of the antenna and the second resonance frequency of the first acoustic resonator.

### CROSS-REFERENCE TO RELATED APPLICATION(S)

This application claims the benefit of and priority to U.S. Provisional Application No. 63/624,879, filed Jan. 25, 2024, which is expressly incorporated by reference herein in its entirety as if fully set forth below and for all applicable purposes.

### TECHNICAL FIELD

Certain aspects of the present disclosure generally relate to electronic components and, more particularly, to filtennas with micro-acoustic resonators.

### BACKGROUND

Electronic devices include traditional computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast and so on. These systems may be capable of supporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems, (e.g., a Long Term Evolution (LTE) system, or a New Radio (NR) system).

Wireless communication transceivers used in these electronic devices generally include multiple radio frequency (RF) filters for filtering a signal for a particular frequency or range of frequencies. Electroacoustic devices (e.g., “acoustic filters”) are used for filtering high-frequency (e.g., generally greater than 100 MHz) signals in many applications. Using a piezoelectric material as a vibrating medium, acoustic resonators operate by transforming an electrical signal wave that is propagating along an electrical conductor into an acoustic wave that is propagating via the piezoelectric material. The acoustic wave propagates at a velocity having a magnitude that is significantly less than that of the propagation velocity of the electromagnetic wave. Generally, the magnitude of the propagation velocity of a wave is proportional to a size of a wavelength of the wave. Consequently, after conversion of an electrical signal into an acoustic signal, the wavelength of the acoustic signal wave is significantly smaller than the wavelength of the electrical signal wave. The resulting smaller wavelength of the acoustic signal enables filtering to be performed using a smaller filter device. This permits acoustic resonators to be used in electronic devices having size constraints, such as the electronic devices enumerated above (e.g., particularly including portable electronic devices, such as smartphones).

Today, surface acoustic wave (SAW) or bulk acoustic wave (BAW) components may be used in wireless communication devices, such as for implementing RF filters. In SAW technology, the acoustic wave propagates laterally on a surface of a piezoelectric substrate, with the movement of the piezoelectric material generated by metal interdigital transducers (IDTs) on the surface. The wavelength of the acoustic wave may be defined by the pitch (e.g., the width of the metal finger and gap) of the IDT. In BAW technology, the acoustic wave propagates vertically through a three-dimensional structure, with an electric field applied through electrodes above and below a piezoelectric material. The wavelength, in this case, is approximately defined by the thickness of the piezoelectric material.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages described herein.

Certain aspects of the present disclosure are directed to a filtenna. The filtenna generally includes an antenna configured to have a first resonance frequency associated with electromagnetic oscillations of the antenna; and one or more acoustic resonators coupled to the antenna, a first acoustic resonator in the one or more acoustic resonators configured to have a second resonance frequency associated with acoustic oscillations of the first acoustic resonator, wherein the filtenna is configured to have a filter transfer function based at least in part on the first resonance frequency of the antenna and the second resonance frequency of the first acoustic resonator.

Certain aspects of the present disclosure are directed to a packaged assembly comprising a filtenna, as described herein.

Certain aspects of the present disclosure are directed to a wireless device. The wireless device generally includes a filtenna, as described herein, and a radio frequency (RF) circuit coupled to the filtenna.

Certain aspects of the present disclosure are directed to an apparatus. The apparatus generally includes an antenna circuit configured to at least one of transmit or receive over a target operating frequency band. The antenna circuit generally includes a radiating element configured to radiate electromagnetic waves, the radiating element having a first resonant frequency different from a center frequency of the target operating frequency band; and one or more acoustic resonators electrically coupled to the radiating element.

Certain aspects of the present disclosure are directed to a method of processing a signal using an antenna circuit configured to at least one of transmit or receive wireless signals over a target operating frequency band. The method generally includes filtering the signal with a radiating element included in the antenna circuit, wherein the radiating element is configured to radiate electromagnetic waves and wherein the radiating element has a first resonant frequency different from a center frequency of the target operating frequency band; and filtering the signal with one or more acoustic resonators included in the antenna circuit and electrically coupled to the radiating element.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1A is a diagram of a perspective view of an example electroacoustic device, in which certain aspects of the present disclosure may be practiced.

FIG. 1B is a diagram of a cross-sectional view of the example electroacoustic device of FIG. 1A.

FIG. 1C is a cross-sectional view of another example electroacoustic device, in which certain aspects of the present disclosure may be practiced.

FIG. 2A is a top view of an example electrode structure of an electroacoustic device, in which certain aspects of the present disclosure may be practiced.

FIG. 2B is a top view of another example electrode structure of an electroacoustic device, in which certain aspects of the present disclosure may be practiced.

FIG. 3A is a diagram of a perspective view of an example electroacoustic device, in which certain aspects of the present disclosure may be practiced.

FIG. 3B is a diagram of a cross-sectional view of the example electroacoustic device of FIG. 3A.

FIG. 4A is a diagram of an antenna and a filter circuit, separated by a transmission line.

FIG. 4B is a diagram of an example filtenna, in accordance with certain aspects of the present disclosure.

FIG. 5A is a circuit diagram of a filtenna where the antenna operates at its series resonance, in accordance with certain aspects of the present disclosure.

FIG. 5B is a circuit diagram of a filtenna where the antenna operates at its parallel resonance, in accordance with certain aspects of the present disclosure.

FIGS. 6A, 6B, and 6C are cross-sectional views of example modules including a filtenna, in accordance with certain aspects of the present disclosure.

FIG. 7 is a block diagram depicting an example dual-polarized filtenna sub-array for phased array applications, in accordance with certain aspects of the present disclosure.

FIG. 8 illustrates a schematic diagram and implementation of an example filtenna circuit, in accordance with certain aspects of the present disclosure.

FIG. 9 is a functional block diagram of at least a portion of an example simplified wireless transceiver circuit in which a filtenna may be employed.

FIG. 10 is a diagram of an environment that includes an electronic device having a wireless transceiver such as the transceiver circuit of FIG. 9.

FIG. 11 is a frequency spectrum illustrating a distribution of example frequency responses and resonance frequencies associated with a filtenna, in accordance with certain aspects of the present disclosure.

FIG. 12 is a flow diagram of example operations for processing a signal using a filtenna, in accordance with certain aspects of the present disclosure.

To facilitate understanding, identical reference numerals have been used, where possible, to designate identical elements that are common to the figures. It is contemplated that elements disclosed in one aspect may be beneficially utilized in other aspects without specific recitation.

### DETAILED DESCRIPTION

Certain aspects of the present disclosure generally relate to a filtenna implemented with micro-acoustic resonators. As used herein, the term “filtenna” is a combination of the words “filter” and “antenna” and describes the combination of a filter and an antenna into one common device. The filter of the filtenna includes one or more micro-acoustic resonators, and the antenna of the filtenna includes a radiating element. In certain aspects, the filtenna may have a filter transfer function based at least in part on the resonance of the radiating element and the resonance(s) of the one or more acoustic resonators. In some cases, the filtenna may be referred to as an “integrated antenna,” an “antenna circuit,” or simply as an “antenna” (with a radiating element and one or more acoustic resonators).

The detailed description set forth below in connection with the appended drawings is intended as a description of exemplary implementations and is not intended to represent the only implementations in which aspects of the present disclosure may be practiced. The term “exemplary” used throughout this description means “serving as an example, instance, or illustration,” and should not necessarily be construed as preferred or advantageous over other exemplary implementations. The detailed description includes specific details for the purpose of providing a thorough understanding of the exemplary implementations. In some instances, some devices are shown in block diagram form. Drawing elements that are common among the following figures may be identified using the same reference numerals.

### Example Electroacoustic Devices

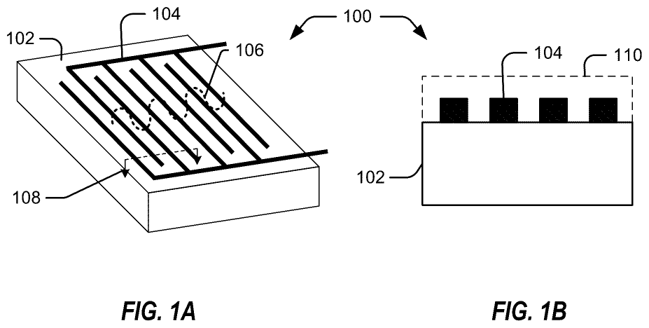

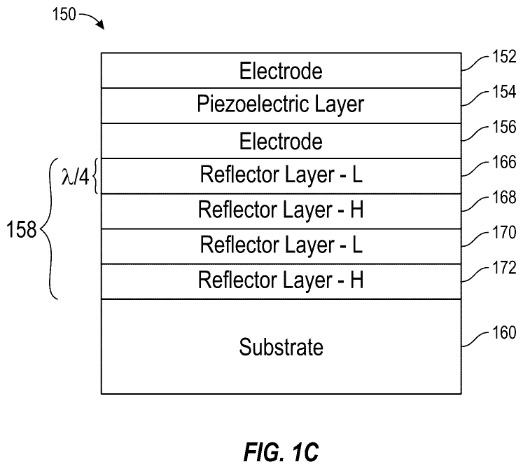

FIG. 1A is a diagram of a perspective view of an example electroacoustic device 100. The electroacoustic device 100 may be configured as or may be a portion of a SAW resonator. In certain descriptions herein, the electroacoustic device 100 itself may be referred to as a SAW resonator. However, while the following description focuses on SAW resonators, the reader is to understand that other electroacoustic device types (e.g., bulk acoustic wave (BAW) resonators (including thin-film bulk acoustic resonators (FBARs) and solidly mounted resonators (SMRs)), micro-electromechanical systems (MEMS) devices, and the like) may be used in place of or in conjunction with SAW resonators.

The electroacoustic device 100 includes an electrode structure 104, that may be referred to as an interdigital transducer (IDT), on the surface of a piezoelectric material 102. The electrode structure 104 generally includes first and second comb-shaped electrode structures (electrically conductive and generally metallic) with electrode fingers extending from two busbars towards each other arranged in an interlocking manner in between the two busbars (e.g., arranged in an interdigitated manner, as shown). An electrical signal excited in the electrode structure 104 (e.g., applying an AC voltage) is transformed into an acoustic wave 106 that propagates in a particular direction via the piezoelectric material 102. The acoustic wave 106 is transformed back into an electrical signal and provided as an output. In many applications, the piezoelectric material 102 has a particular crystal orientation such that when the electrode structure 104 is arranged relative to the crystal orientation of the piezoelectric material 102, the acoustic wave mainly propagates in a direction perpendicular to the direction of the fingers (e.g., parallel to the busbars).

FIG. 1B is a diagram of a cross-sectional view of the electroacoustic device 100 of FIG. 1A along a cross-section 108 shown in FIG. 1A. The electroacoustic device 100 is illustrated by a simplified layer stack including the piezoelectric material 102 with the electrode structure 104 disposed on the piezoelectric material 102. The electrode structure 104 is electrically conductive and generally formed from metallic materials. The electrode structure 104 may alternatively be formed from materials that are electrically conductive, but non-metallic (e.g., graphene). The piezoelectric material 102 may be formed from a variety of materials such as quartz, lithium tantalate (LiTaO₃), lithium niobite (LiNbO₃), doped variants of these, other piezoelectric materials, or other crystals. The piezoelectric material 102 may be referred to as a “piezoelectric substrate,” but may also be referred to as a “piezoelectric layer,” such as in examples where there are additional layers below the piezoelectric material 102.

It should be appreciated that more complicated layer stacks including layers of various materials may be possible within the stack. For example, optionally, a temperature compensation layer 110 denoted by the dashed lines may be disposed above the electrode structure 104. The piezoelectric material 102 may be extended with multiple interconnected electrode structures disposed thereon to form a multi-resonator filter or to provide multiple filters. While not illustrated, when provided as an integrated circuit component, a cap layer may be provided over the electrode structure 104. The cap layer is applied so that a cavity is formed between the electrode structure 104 and an under surface of the cap layer. Electrical vias or bumps that allow the component to be electrically connected to connections on a substrate (e.g., via flip-chip or other techniques) may also be included.

FIG. 1C is a cross-sectional view of an electroacoustic device 150. The electroacoustic device 150 may be configured as or be a portion of a BAW resonator, such as an SMR-type BAW. As shown, the electroacoustic device 150 includes a top electrode 152, a piezoelectric layer 154, a bottom electrode 156, a Bragg reflector 158, and a substrate 160.

As shown, the top electrode 152 is disposed above the piezoelectric layer 154. The top electrode 152 may include an electrically conductive material such as a metal or metal alloy including aluminum (Al), chromium (Cr), cobalt (Co), copper (Cu), gold (Au), molybdenum (Mo), platinum (Pt), ruthenium (Ru), tantalum (Ta), titanium (Ti), tungsten (W), a combination thereof (e.g., AlCu), or any other suitable material. In certain cases, the conductive material may include graphene or other electrically conductive, non-metallic materials. The piezoelectric layer 154 may include a piezoelectric material, such as aluminum nitride (AlN), aluminum scandium nitride (AlScN), zinc oxide (ZnO), a quartz crystal (such as lithium tantalate (LiTaO₃) or lithium niobite (LiNbO₃)), doped variants of these, or other suitable piezoelectric materials.

The bottom electrode 156 may include an electrically conductive material such as a metal or metal alloy, for example, as described herein with respect to the top electrode 152. In certain aspects, the bottom electrode 156 may have the same form, size, and/or structure as the top electrode 152. For example, the electrodes 152, 156 may both be electrode plates. In certain cases, the bottom electrode 156 may have a different form, size, and/or structure from the top electrode 152.

The Bragg reflector 158 may acoustically isolate the BAW resonator from the substrate 160 or at least reduce the acoustic coupling between the BAW resonator and the substrate 160. In general, the Bragg reflector 158 may include alternating layers of materials having low acoustic impedance and materials having high acoustic impedance, as further described herein with respect to FIG. 1C.

The substrate 160 may be disposed below the Bragg reflector 158, such that the substrate 160 is arranged under the top electrode 152 and the bottom electrode 156. The substrate 160 may serve as a carrier for the BAW resonator. In some aspects, the substrate 160 may be formed from a semiconductor wafer, such as a silicon (Si) wafer. The substrate 160 may comprise any of various other suitable materials, such as alumina (Al₂O₃), glass, or sapphire.

When an electrical signal (e.g., an AC voltage signal) is applied to the electrodes 152 and 156, the electrical signal is transformed into an acoustic wave 162 that propagates in the piezoelectric layer 154. That is, applying an electrical signal to the piezoelectric layer 154 between the electrodes 152 and 156 transduces the electrical signal to the acoustic wave 162 in the piezoelectric layer 154. At certain frequencies, a resonant and/or anti-resonant mechanical standing wave may be formed, thus enabling the filter functionality. As noted above, to avoid leakage into the substrate 160, the Bragg reflector 158 may be disposed below the bottom electrode 156. The Bragg reflector 158 may have high acoustic reflectivity and may reflect an acoustic wave 164 back towards the piezoelectric layer 154 and the top electrode 152. Reflecting the acoustic waves 164 may enhance the efficiency of the BAW resonator and acoustically decouple the substrate 160 from the BAW resonator. In many applications, the piezoelectric layer 154 has a particular crystal orientation such that when the top electrode 152 is arranged relative to the crystal orientation of the piezoelectric layer 154, the acoustic wave mainly propagates in a direction from the top electrode 152 to the bottom electrode 156.

FIG. 1C also illustrates example reflector layers of the Bragg reflector 158 in the electroacoustic device 150. In this example, the Bragg reflector 158 includes a reflector layer 166, a reflector layer 168, a reflector layer 170, and a reflector layer 172. In certain cases, the Bragg reflector 158 may have any suitable number of reflector layers, such as fewer or more than four reflector layers as depicted in this example. The reflector layer 168 and reflector layer 172 may include a material having an acoustic impedance that is higher (as indicated by the “Reflector Layer-H” label) than the acoustic impedance of a material of the reflector layer 166 and reflector layer 170 (as indicated by the “Reflector Layer-L” label). For example, the reflector layer 166 and reflector layer 170 may include silicon dioxide (SiO₂) or aluminum nitride (AlN), whereas the reflector layer 168 and reflector layer 172 may include tungsten (W) or another suitable material with a higher acoustic impedance than silicon dioxide or aluminum nitride.

The reflector layers 166, 168, 170, 172 may have the same thickness (e.g., a quarter wavelength (λ/4) in thickness according to the operating frequency range of the electroacoustic device 150) or vary in thickness. While in this example, the reflector layers 166, 168, 170, 172 are depicted as having the same length, the reflector layers 166, 168, 170, 172 may vary in length (i.e., individual layers may have different lengths).

Although FIG. 1C is depicted as an SMR-type BAW resonator, it is to be understood that certain aspects of the present disclosure may alternatively be implemented with other types of BAW resonators, such as thin-film bulk acoustic resonators (FBARs).

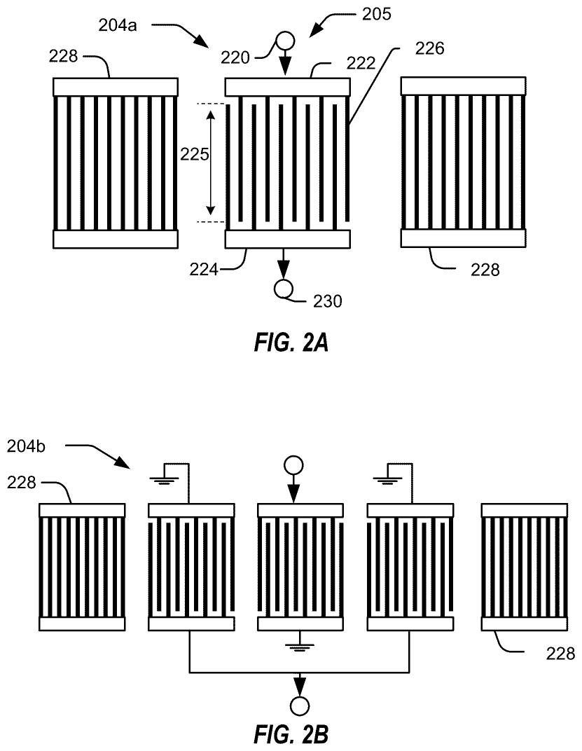

FIG. 2A is a top view of an example electrode structure 204a of an electroacoustic device. The electrode structure 204a has an IDT 205 that includes a first busbar 222 (e.g., first conductive segment or rail) electrically coupled to a first terminal 220 and a second busbar 224 (e.g., second conductive segment or rail) spaced from the first busbar 222 and coupled to a second terminal 230. A plurality of conductive fingers 226 are connected to either the first busbar 222 or the second busbar 224 in an interdigitated manner. Fingers 226 connected to the first busbar 222 extend towards the second busbar 224 but do not connect to the second busbar 224 so that there is a small gap between the ends of these fingers 226 and the second busbar 224. Likewise, fingers 226 connected to the second busbar 224 extend towards the first busbar 222 but do not connect to the first busbar 222 so that there is a small gap between the ends of these fingers 226 and the first busbar 222. Similarly, small gaps may also be formed between fingers 226 and any structure extending from the first busbar 222 or the second busbar 224 (e.g., stub fingers).

Between the busbars, there is an overlap region including a central region where a portion of one finger overlaps with a portion of an adjacent finger as illustrated by the central region 225. This central region 225 including the overlap may be referred to as the aperture, track, or active region where electric fields are produced between the fingers 226 to cause an acoustic wave to propagate in this region of the piezoelectric material 102. The periodicity of the fingers 226 is referred to as the pitch of the IDT. The pitch may be indicated in various ways. For example, in certain aspects, the pitch may correspond to a magnitude of a distance between fingers in the central region 225. This distance may be defined, for example, as the distance between center points of each of the fingers (and may be generally measured between a right (or left) edge of one finger and the right (or left) edge of an adjacent finger when the fingers have uniform width). In certain aspects, an average of distances between adjacent fingers may be used as the pitch. The frequency at which the piezoelectric material vibrates is a main resonance frequency of the electrode structure 204a. This frequency is determined at least in part by the pitch of the IDT 205 and other properties of the electroacoustic device 100.

The IDT 205 is arranged between two reflectors 228 which reflect the acoustic wave back towards the IDT 205 for the conversion of the acoustic wave into an electrical signal via the IDT 205 in the configuration shown and to prevent losses (e.g., confine and prevent escaping acoustic waves). Each reflector 228 has two busbars and a grating structure of conductive fingers that each connect to both busbars. The pitch of the reflector may be similar to or the same as the pitch of the IDT 205 to reflect acoustic waves in the resonant frequency range. But many configurations are possible.

When converted back to an electrical signal, the converted electrical signal may be provided as an output, such as to one of the first terminal 220 or the second terminal 230, while the other terminal may function as an input.

A variety of electrode structures are possible. FIG. 2A may generally illustrate a one-port configuration. Other configurations (e.g., two-port configurations) are also possible. For example, the electrode structure 204a may have an input IDT 205 where each terminal 220 and 230 functions as an input. In this event, an adjacent output IDT (not illustrated) that is positioned between the reflectors 228 and adjacent to the input IDT 205 may be provided to convert the acoustic wave propagating in the piezoelectric material 102 to an electrical signal to be provided at output terminals of the output IDT.

FIG. 2B is a top view of another example electrode structure 204b of an electroacoustic device. In this case, a dual-mode SAW (DMS) electrode structure 204b is illustrated, the DMS structure being a structure that may induce multiple resonances. The electrode structure 204b includes multiple IDTs arranged between reflectors 228 and connected as illustrated. The electrode structure 204b is provided to illustrate the variety of electrode structures in which principles described herein may be applied.

It should be appreciated that while a certain number of fingers 226 are illustrated, the number of actual fingers and length(s) and width(s) of the fingers 226 and busbars may be different in an actual implementation. Such parameters depend on the particular application and desired filter characteristics. In addition, a SAW filter may include multiple interconnected electrode structures each including multiple IDTs to achieve a desired passband (e.g., multiple interconnected resonators or IDTs to form a desired filter transfer function).

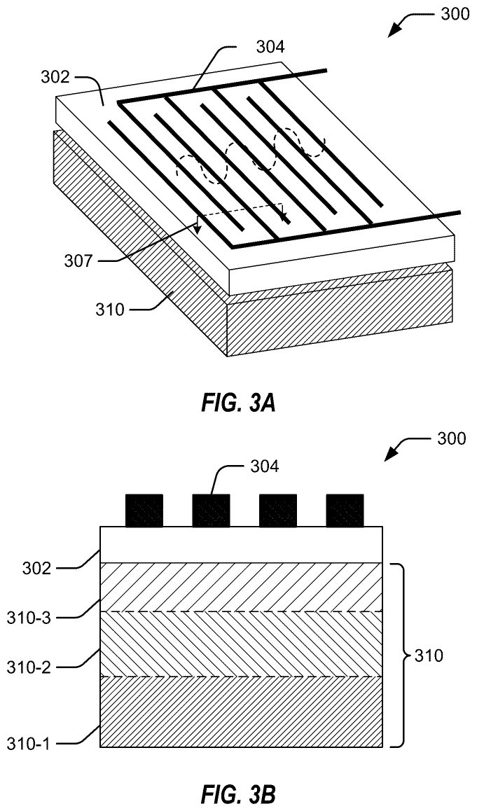

FIG. 3A is a diagram of a perspective view of another example of an electroacoustic device 300. The electroacoustic device 300 (e.g., that may be configured as or be a part of a SAW resonator) is similar to the electroacoustic device 100 of FIG. 1A but has a different layer stack. In particular, the electroacoustic device 300 includes a thin piezoelectric material 302 that is provided on a substrate 310 (e.g., silicon). The electroacoustic device 300 may be referred to as a thin-film SAW resonator (TF-SAW) in some cases. Based on the type of piezoelectric material 302 used (e.g., typically having higher coupling factors relative to the electroacoustic device 100 of FIG. 1A) and a controlled thickness of the piezoelectric material 302, the particular acoustic wave modes excited may be slightly different than those in the electroacoustic device 100 of FIG. 1A. Based on the design (thicknesses of the layers, and selection of materials, etc.), the electroacoustic device 300 may have a higher quality factor (Q) as compared to the electroacoustic device 100 of FIG. 1A. In general, the substrate 310 may be substantially thicker than the piezoelectric material 302 (e.g., on the order of 50 to 100 times thicker, or more). The substrate 310 may include other layers (or other layers may be included between the substrate 310 and the piezoelectric material 302).

FIG. 3B is a diagram of a cross-sectional view of the electroacoustic device 300 of FIG. 3A showing an exemplary layer stack (along a cross-section 307). In the example shown in FIG. 3B, the substrate 310 may include sublayers such as a substrate sublayer 310-1 (e.g., of silicon) that may have a higher resistance (e.g., relative to the other layers—a high resistivity layer). The substrate 310 may further include a trap rich layer 310-2 (e.g., polysilicon). The substrate 310 may further include a compensation layer 310-3 (e.g., silicon dioxide (SiO₂) or another dielectric material) that may provide temperature compensation and other properties. These sublayers may be considered part of the substrate 310 or their own separate layers. A relatively thin piezoelectric material 302 is provided on the substrate 310 with a particular thickness for providing a particular acoustic wave mode (e.g., as compared to the electroacoustic device 100 of FIG. 1A where the thickness of the piezoelectric material 102 may not be a significant design parameter beyond a certain thickness and may be generally thicker as compared to the piezoelectric material 302 of the electroacoustic device 300 of FIGS. 3A and 3B). The electrode structure 304 is positioned above the piezoelectric material 302. In addition, in some aspects, there may be one or more layers (not shown) possible above the electrode structure 304 (e.g., such as a thin passivation layer).

Based on the type of piezoelectric material, the thickness, and the overall layer stack, the coupling to the electrode structure 304 and acoustic velocities within the piezoelectric material in different regions of the electrode structure 304 may differ between different types of electroacoustic devices, such as between the electroacoustic device 100 of FIG. 1A and the electroacoustic device 300 of FIGS. 3A and 3B.

### Example Filtenna with Micro-Acoustic Resonators

Traditionally, the filtering portion of a radio frequency front-end (RFFE) is accomplished with one or more filters coupled to a device's antenna, which may be matched to the characteristic impedance of the RFFE. However, depending on the desired size of the matched antenna and the specifications of the filter(s), connecting the filter(s) directly to the matched antenna may not be feasible. As a result, an additional transmission line is typically used to connect the matched antenna with the filter(s), adding additional loss in the signal chain. The antennas considered in such systems are typically matched to the system characteristic impedance Z₀ (e.g., Z₀=50 Ω), as are the filters.

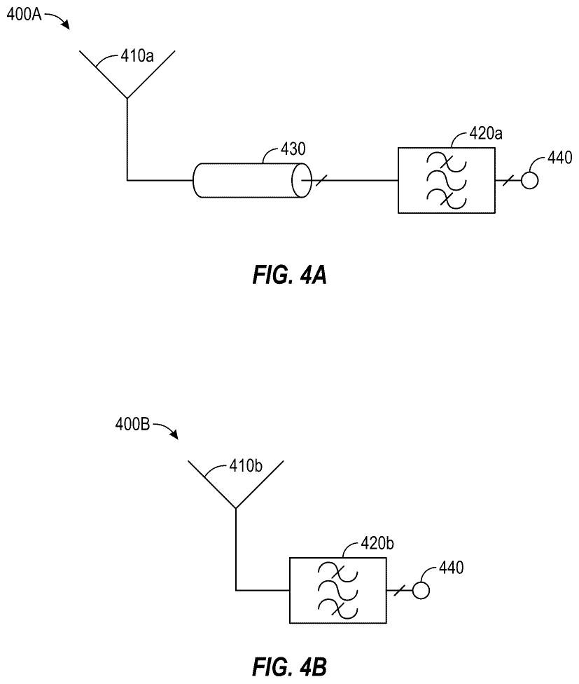

FIG. 4A is a diagram 400A of an antenna 410a and a filter circuit 420a, coupled by and separated by a transmission line 430. The filter circuit 420a may be coupled to a port 440. In this case, the antenna 410a may be designed separately from the filter circuit 420a and may have a frequency behavior that is independent from the filter circuit 420a. The antenna 410a and/or the filter circuit 420a may be designed to match a characteristic impedance (e.g., 50 Ω) of a radio frequency (RF) transmitter or receiver.

According to certain aspects of the present disclosure, the antenna and the filter circuit can be combined in what is referred to herein as a “filtenna,” where the antenna is an integral part of the filter. FIG. 4B is a diagram of an example filtenna 400B including an antenna 410b and a filter circuit 420b, in accordance with certain aspects of the present disclosure.

The combination of the filter circuit into the antenna design in a filtenna has some advantages. By utilizing the antenna 410b as one resonator being part of the overall filtenna filter, the transmission line losses and matching losses present in some approaches may be minimized, or at least significantly reduced. Note, that in this case, the antenna 410b need not be matched to a characteristic impedance. In some aspects, the filtenna 400B may be realized in a module (e.g., a packaged assembly) using acoustic resonators along with a radiating element (e.g., an antenna element such as a patch, dipole, and the like). The acoustic resonators may be implemented by any of various suitable devices, such as BAW resonators (including FBARs and SMRs), SAW resonators, MEMS devices, or any combination thereof. The antenna portion of the filtenna 400B may be designed to operate based on the wave speed of light (e.g., electromagnetic oscillations), whereas the acoustic resonators may be designed to operate based on a different wave speed, the speed of sound (e.g., acoustic oscillations) in a solid body.

The filtenna concept is different from some approaches in the sense that the filter circuit 420b and the antenna 410b in the filtenna 400B are co-designed. Furthermore, the impedance of the filtenna 400B can be anything, as this may only be dictated by the filtering specifications and the theoretical boundaries as given by filter theory (e.g., coupling matrix designs). An advantage of the filtenna 400B may be a significant reduction of ohmic losses, which may not only increase the signal fidelity, but may also improve the overall system performance (less power consumption, less generated heat, etc.). In addition, highly compact filtenna designs are achievable, as the antenna 410b and the filter circuit 420b can be integrated into a very compact module. In certain aspects, the antenna 410b used in the filtenna 400B may have a quality factor (Q) higher than 10, and/or a radiation efficiency greater than 80%.

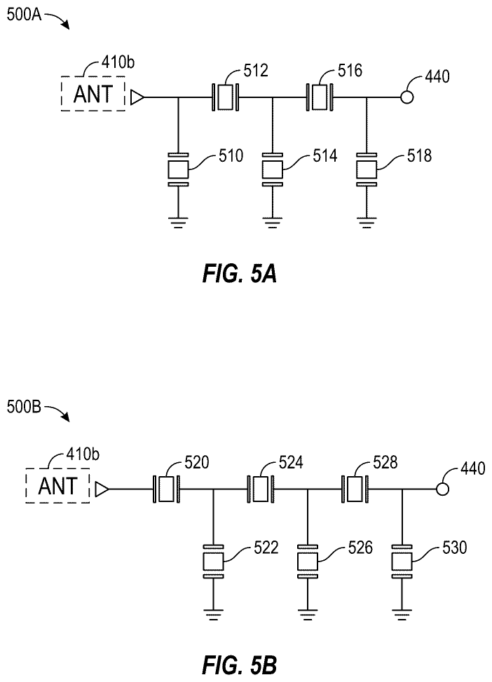

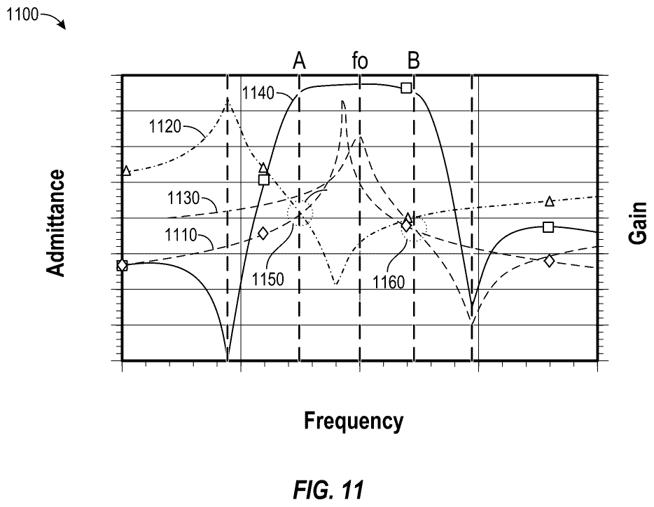

In a filtenna, the first resonator of the considered filter topology is the antenna itself (e.g., the radiating element). This sets boundary conditions for the following stages. If the antenna is designed to operate at its series resonance, then the following acoustic resonator of the filtenna should be a parallel resonance circuit (the antenna is considered as the first resonator, having series resonance). FIG. 5A is a circuit diagram of a filtenna 500A where the antenna 410b (labeled “ANT”) is designed to operate at its series resonance, in accordance with certain aspects of the present disclosure. In this case, an acoustic resonator 510 coupled in shunt may follow the antenna 410b, as shown. If the antenna 410b is designed to operate at its parallel resonance, then the following acoustic resonator 510 of the filtenna should be a series resonance circuit (the antenna 410b is considered as the first resonator, having parallel resonance). FIG. 5B is a circuit diagram of a filtenna 500B where the antenna 410b is designed to operate at its parallel resonance, in accordance with certain aspects of the present disclosure. In this case, an acoustic resonator 520 may be coupled in series with the antenna 410b, as shown. In either case, the resonance of the antenna 410b is designed as part of the overall filtenna filter response and may be offset from the center frequency of the filtenna's frequency band (as is also described below with respect to FIG. 11), unlike in some approaches where the antenna is designed independently from the filter circuit and may have a resonance at the center frequency. In this manner, the antenna 410b (used as the first resonator) and the one or more acoustic resonators together may form a combined filter circuit having a passband (or other desired filter response (e.g., low pass, high pass, notch, or bandstop)) corresponding to the target operating frequency band of the filtenna. In one example, the antenna 410b may provide a series resonance at 13.05 GHz and a parallel resonance at 11.2 GHz.

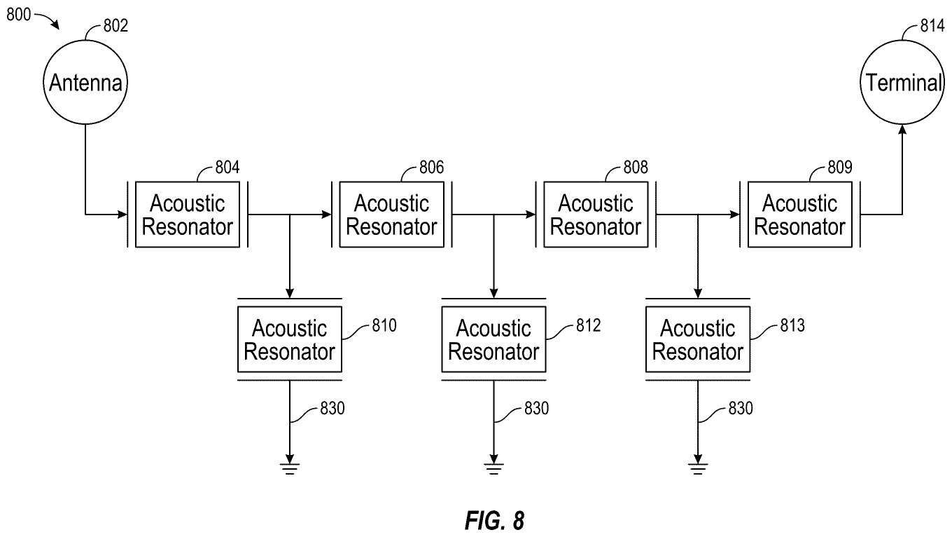

Multiple resonators can be coupled together, following a ladder-type architecture (e.g., as shown in FIGS. 5A, 5B, and 8) in a filtenna to achieve higher-order filters and a particular filter transfer function. For example, a filtenna may include a ladder-type architecture with the antenna 410b (used as the first resonator with series resonance) and with shunt acoustic resonators 510, 514, 518 and series acoustic resonators 512, 516 coupled in an alternating fashion between the antenna 410b and the port 440, as shown in the filtenna 500A of FIG. 5A. That is, in a ladder-type architecture, series acoustic resonator 512 follows shunt acoustic resonator 510, shunt acoustic resonator 514 follows series acoustic resonator 512, and so forth. In another example, a filtenna may include a ladder-type architecture with the antenna 410b (used as the first resonator with parallel resonance) and with series acoustic resonators 520, 524, 528, and shunt acoustic resonators 522, 526, 530 coupled in an alternating fashion between the antenna 410b and the port 440, as shown in the filtenna 500B of FIG. 5B. As described above, the acoustic resonators may be implemented by any of various suitable devices, such as BAW resonators (including FBARs and SMRs), SAW resonators, MEMS devices, or any combination thereof.

In case the coupling of the acoustic resonators (e.g., acoustic resonators 510, 512, 514, 516, 518, 520, 522, 524, 526, 528, and/or 530) is insufficient to achieve a particular filter design, inductors coupled in parallel with at least some of the acoustic resonators may correct, or at least adjust for this situation. Additionally or alternatively, inductors connected in series with the acoustic resonators (e.g., shunt acoustic resonators and/or series acoustic resonators) may improve the filtenna performance, such as in cases where the technology-defined micro-acoustic resonator gap (between series resonance and parallel resonance) would not be sufficient to cover the entire filtenna bandwidth. Furthermore, capacitors may be coupled either in series or in parallel with the acoustic resonators.

If the port 440 should be matched to the characteristic impedance (e.g., 50 Ω) of the RFFE, an impedance converter (not illustrated) may be coupled to the port 440. An impedance converter may be implemented, in its simplest form, as a two-element inductor-capacitor (LC) network, while other implementations with different LC configurations or impedance converter circuits are contemplated.

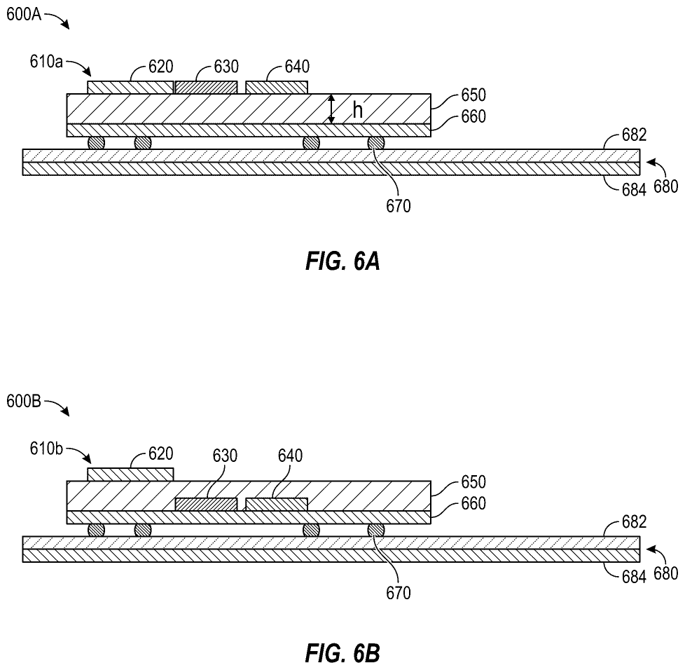

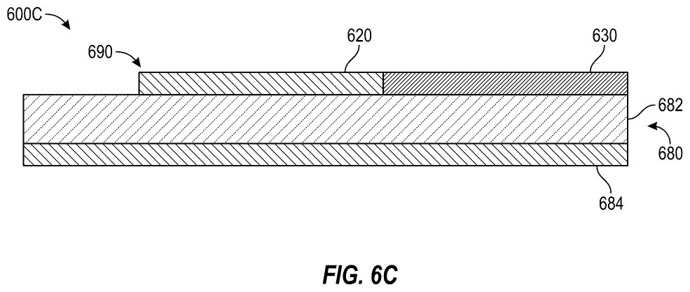

FIG. 6A is a cross-sectional view of an example module 600A including a filtenna submodule 610a disposed above a printed circuit board (PCB) 680, in accordance with certain aspects of the present disclosure. In the filtenna submodule 610a, an antenna 620 (e.g., being or including a radiating element, such as a patterned metal radiating element) and an acoustic chip 630 (with one or more acoustic resonators) are disposed adjacent to one another above a substrate 650. In some aspects, the antenna 620 may be electrically coupled to the one or more acoustic resonators of the acoustic chip 630. The antenna 620 and the other antennas described herein may be implemented, for example, by patch antennas, inverted-L antennas, inverted-F antennas (e.g., planar inverted-F antennas), inverted-V antennas, or the like. When the antenna 620 is implemented with a patch antenna as a radiating element, the radiating element may be implemented in the form of a rectangle, a square, a circular disc, a ring, a triangle, a dipole, or any of other various suitable forms.

The substrate 650 may be implemented with a dielectric layer (e.g., a high-Q dielectric later) having a height h, as shown. The substrate 650 may be disposed above a metal layer 660, which may include one or more electrically conductive traces and/or planes. At least part of the metal layer 660 may function as an antenna ground plane or a filtenna ground plane. The trace(s) and/or plane(s) in metal layer 660 may be coupled to one or more solder balls 670 or other suitable electrically conductive structures for coupling the filtenna submodule 610a to the PCB 680 to form the module 600A. The PCB 680 may include a dielectric layer 682 disposed above a metal layer 684 (e.g., a ground plane layer). The PCB 680 may also include one or more traces (not illustrated) disposed above the dielectric layer 682. These traces may include conductive pads in the PCB 680, which may be soldered or otherwise coupled to the solder balls 670 of the filtenna submodule 610a to mechanically attach and electrically couple the filtenna submodule 610a to the PCB 680 to form the module 600A. The location of the filtenna submodule 610a on the PCB 680 may be flexible.

In some cases, the PCB 680 may be part of wireless device PCB (e.g., a smartphone PCB) that includes multiple dielectric layers and multiple metal layers. In these cases, the filtenna module 610a may be soldered (or otherwise attached with suitable electrical connection) directly onto the wireless device PCB that includes the PCB 680.

In some aspects, one or more active devices 640 (e.g., a power amplifier (PA), a low noise amplifier (LNA), a switch, or the like) may optionally be included in the module 600A. In such cases, the active device(s) 640 may be disposed above the substrate 650 in the filtenna submodule 610a, such as adjacent to the acoustic chip 630.

FIG. 6B is a cross-sectional view of an example module 600B including a filtenna submodule 610b, in accordance with certain aspects of the present disclosure. The module 600B may be similar to the module 600A, and may include the antenna 620 (e.g., a patterned metal radiating element), the acoustic chip 630, one or more active devices 640, substrate 650, the metal layer 660, the one or more solder balls 670, and the PCB 680 with the dielectric layer 682 and the metal layer 684. In the module 600B, however, the antenna 620 is disposed above the substrate 650 of the filtenna submodule 610b, whereas the acoustic chip 630 is buried in the substrate 650 and disposed above the metal layer 660. The optional active device(s) 640 may also be buried in the substrate 650 and disposed above the metal layer 660, as shown.

FIG. 6C is a cross-sectional view of an example module 600C including a filtenna 690, in accordance with certain aspects of the present disclosure. The module 600C may include the antenna 620, the acoustic chip 630, and the PCB 680 with the dielectric layer 682 and the metal layer 684. Unlike the modules 600A, 600B, the module 600C may not include a filtenna submodule disposed above the PCB 680 and coupled thereto with solder balls 670. Instead, the module 600C, the antenna 620, the acoustic chip 630, and/or optional active device(s) 640 (not illustrated) of the filtenna 690 may be disposed directly on the PCB 680. In this manner, the height of the module 600C may be equal to or not much greater than the height of the PCB 680.

In certain aspects, the one or more acoustic resonators included in the acoustic chip 630 may be formed on one die and separated from the antenna 620 (where the antenna may be formed on another die and may be used as one resonator of the filtenna). In other aspects, the antenna 620 and the one or more acoustic resonators in the acoustic chip 630 may be packaged in a common package. The antenna 620 and the one or more acoustic resonators in the acoustic chip 630 may be co-located together such that a conductive line coupling the antenna 620 to the one or more acoustic resonators forms a portion of the antenna 620.

Optionally a phase shifter can be added and coupled to the filtenna in any of the modules 600A, 600B, 600C. This optional phase shifter may be included, for example, in cases where the module is part of a more complex phased-array configuration.

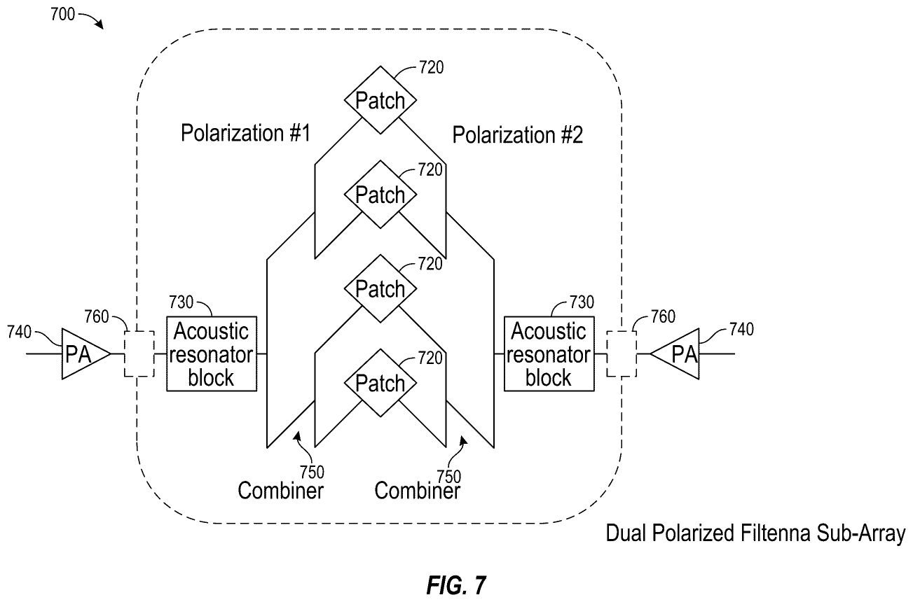

FIG. 7 is a block diagram depicting an example dual-polarized filtenna sub-array 700 for phased-array applications, in accordance with certain aspects of the present disclosure. The dual-polarized filtenna sub-array 700 may include multiple antennas 720 (each labeled “Patch”), acoustic resonator blocks 730 (each with one or more acoustic resonators), and combiners 750. As illustrated, the acoustic resonator blocks 730 of the filtenna sub-array 700 may be coupled to active devices 740 (e.g., amplifiers, such as PAs as shown). Although not illustrated, the dual-polarized filtenna sub-array 700 may also be coupled to additional active devices (e.g., PAs, LNAs, switches, etc.). In certain aspects, the dual-polarized filtenna sub-array 700 may include or be coupled to one or more optional impedance converters 760. The dual-polarized filtenna sub-array 700 may support two linear polarizations (e.g., Polarization #1 and Polarization #2), as shown.

### Example Resonance Distribution for a Filtenna

FIG. 11 is a frequency spectrum 1100 illustrating a distribution of example frequency responses and resonance frequencies associated with a filtenna (e.g., a three-pole filtenna), in accordance with certain aspects of the present disclosure. The spectrum 1100 illustrates an admittance of an antenna 1110, an admittance of an acoustic resonator in shunt 1120, and an admittance of an acoustic resonator in series 1130, over frequency. When combined, the admittance of the antenna 1110, the admittance of the acoustic resonator in shunt 1120, and the admittance of the acoustic resonator in series 1130, over frequency, may form a passband of a bandpass frequency response of a filtenna 1140 (e.g., a filter transfer function of the filtenna, illustrating gain over frequency). The passband may be characterized by a center frequency (e.g., labeled “f0”) and a bandwidth (e.g., the range from frequency A to frequency B). The passband of the frequency response of the filtenna 1140 may be approximately defined by an intersection 1150 of the admittances of the antenna 1110 and the acoustic resonator in shunt 1120 (e.g., at frequency A) below the center frequency and an intersection 1160 of the admittances of the antenna 1110 and the acoustic resonator in series 1130 (e.g., at frequency B) above the center frequency. For example, the passband of the filtenna may range from 12752MHz to 13229 MHz.

### Example Filtenna Operations

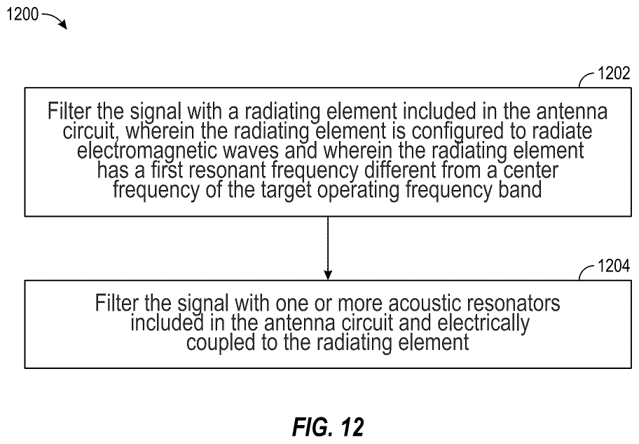

FIG. 12 is a flow diagram of example operations 1200 for processing a signal using an antenna circuit (e.g., filtenna 400B, 500A, 500B, 690, filtenna submodule 610a, 610b, or filtenna circuit 800 of FIGS. 4B, 5A, 5B, 6A-C, and 8), in accordance, with certain aspects of the present disclosure. The antenna circuit may be configured to at least one of transmit or receive wireless signals over a target operating frequency band.

The operations 1200 may include, at block 1202, filtering the signal with a radiating element (e.g., antenna 410b, antenna 620, antenna 720, antenna 802) included in the antenna circuit. The radiating element may be configured to radiate electromagnetic waves and may have a first resonant frequency different from a center frequency (e.g., center frequency f0) of the target operating frequency band.

At block 1204, the operations 1200 may include filtering the signal with one or more acoustic resonators (e.g., acoustic resonators 510, 512, 514, 516, 518, 520, 522, 524, 526, 528, 530, 804, 806, 808, 809, 810, 812, 813 and acoustic resonator blocks 730) included in the antenna circuit and electrically coupled to the radiating element.

In certain aspects, the radiating element and the one or more acoustic resonators may together form a combined filter circuit having a passband corresponding to the target operating frequency band.

### Example Applications of a Filtenna

FIG. 8 illustrates a schematic diagram of an example filtenna circuit 800 using micro-acoustic resonators, in accordance with certain aspects of the present disclosure. The filtenna circuit 800 includes an antenna 802-for example, including a radiating element (functioning as an input or output terminal for the circuit, as well as a resonator of the filtenna circuit)-and a terminal 814 (which may function as an output or input terminal, respectively, for the circuit). Between the antenna 802 and the terminal 814, a ladder-type network of acoustic resonators is provided. The acoustic resonators may be implemented by any of various suitable devices, such as BAW resonators (including solidly mounted resonator (SMR)-type BAW resonators), SAW resonators, thin-film bulk acoustic resonators (FBARs), micro-electromechanical systems (MEMS) devices, or any combination thereof. The filtenna circuit 800 includes a first acoustic resonator 804, a second acoustic resonator 806, a third acoustic resonator 808, and a fourth acoustic resonator 809, all electrically connected in a series path between the antenna 802 and the terminal 814. A fifth acoustic resonator 810 (e.g., a shunt resonator) has a first terminal connected to a node between the first acoustic resonator 804 and the second acoustic resonator 806 and has a second terminal connected to a reference potential node 830 (e.g., electric ground) for the filtenna circuit 800. A sixth acoustic resonator 812 (e.g., a shunt resonator) has a first terminal connected to a node between the second acoustic resonator 806 and the third acoustic resonator 808 and has a second terminal connected to the reference potential node 830. A seventh acoustic resonator 813 (e.g., a shunt resonator) has a first terminal connected to a node between the third acoustic resonator 808 and the fourth acoustic resonator 809 and has a second terminal connected to the reference potential node 830. Although not shown, any of the acoustic resonators in the filtenna circuit 800 may be coupled in series or in parallel with additional passive elements, such as one or more inductors and/or one or more capacitors.

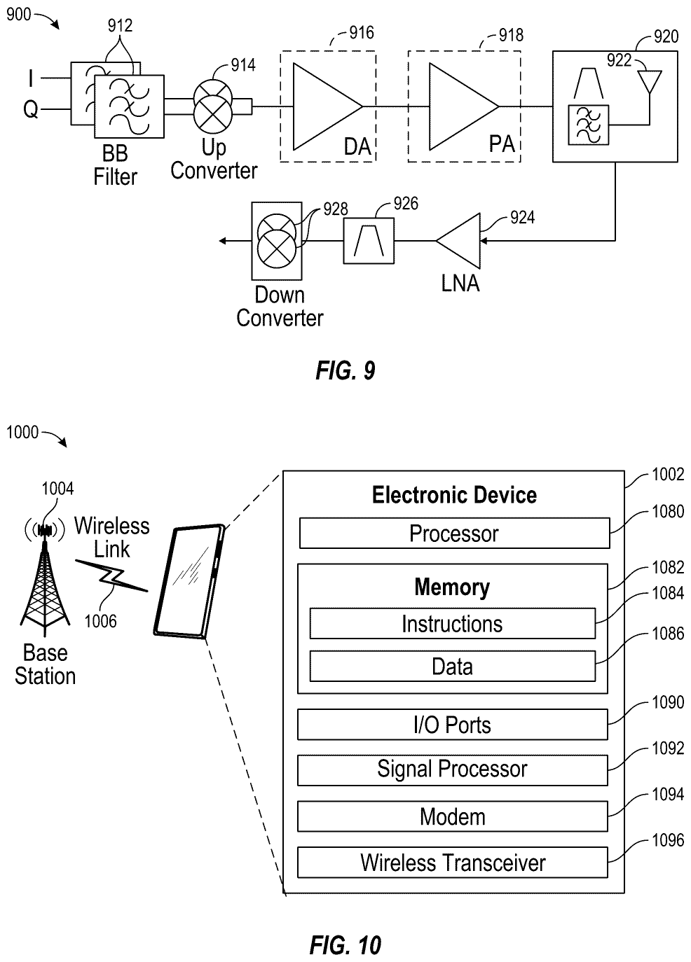

FIG. 9 is a functional block diagram of at least a portion of an example of a simplified wireless transceiver circuit 900 in which a filtenna (e.g., the filtenna 400B of FIG. 4B) or filtenna circuit (e.g., the filtenna circuit 800 of FIG. 8) may be employed. The transceiver circuit 900 is configured to receive signals/information for transmission (shown as in-phase (I) and quadrature (Q) values) which is provided to one or more baseband (BB) filters 912. The filtered output is provided to one or more mixers 914 for upconversion to radio frequency (RF) signals. The output from the one or more mixers 914 may be provided to a driver amplifier (DA) 916 whose output may be provided to a power amplifier (PA) 918 to produce an amplified signal for wireless transmission. The amplified signal may be output to the antenna 922 through one or more filters including a filtenna 920 (of which the antenna 922 is a part). The filtenna 920 may be implemented by any suitable filtenna or filtenna circuit.

The antenna 922 may be used for both wirelessly transmitting and receiving signals (e.g., using a transmit/receive (T/R) switch (not shown) for time-division duplexing (TDD)). The transceiver circuit 900 includes a receive path through the one or more filters (e.g., through the filtenna 920) to be provided to a LNA 924 and a further filter 926 and then downconverted from the receive frequency to a baseband frequency through one or more mixer circuits 928 before the signal is further processed (e.g., provided to an analog-to-digital converter (ADC) and then demodulated or otherwise processed in the digital domain). There may be separate filters for the receive circuit (e.g., the receive circuit may have a separate antenna or have separate receive filters) that may be implemented using any suitable filtenna or filtenna circuit.

FIG. 10 is a diagram of an environment 1000 that includes an electronic device 1002, in which aspects of the present disclosure may be practiced. In the environment 1000, the electronic device 1002 communicates with a base station 1004 (or other network node) through a wireless link 1006. As shown, the electronic device 1002 is depicted as a smartphone. However, the electronic device 1002 may be implemented as any suitable computing or other electronic device, such as a cellular base station, broadband router, access point, cellular or mobile phone, gaming device, navigation device, media device, laptop computer, desktop computer, tablet computer, server computer, network-attached storage (NAS) device, smart appliance, vehicle-based communication system, Internet of Things (IoT) device, sensor or security device, asset tracker, extended reality device, wearable device, and so forth.

The base station 1004 communicates with the electronic device 1002 via the wireless link 1006, which may be implemented as any suitable type of wireless link. Although depicted as a base station tower of a cellular radio network, the base station 1004 may represent or be implemented as another device, such as a satellite, terrestrial broadcast tower, access point, peer-to-peer device, mesh network node, fiber optic line, another electronic device generally as described above, and so forth. Hence, the electronic device 1002 may communicate with the base station 1004 or another device via a wired connection, a wireless connection, or a combination thereof. The wireless link 1006 can include a downlink of data or control information communicated from the base station 1004 to the electronic device 1002 and an uplink of other data or control information communicated from the electronic device 1002 to the base station 1004. The wireless link 1006 may be implemented using any suitable communication protocol or standard, such as 3rd Generation Partnership Project Long-Term Evolution (3GPP LTE), 3GPP New Radio (NR) 5G, IEEE 802.11, IEEE 802.15, IEEE 802.16, Bluetooth™, and so forth.

The electronic device 1002 includes at least one processor 1080 and at least one memory 1082. The memory 1082 may be or form a portion of a computer-readable storage medium. The processor 1080 may include any type of processor, such as an application processor or a multi-core processor, that is configured to execute processor-executable instructions (e.g., code) stored by the memory 1082. The memory 1082 may include any suitable type of data storage media, such as volatile memory (e.g., random access memory (RAM)), non-volatile memory (e.g., flash memory), optical media, magnetic media (e.g., disk or tape), and so forth. In the context of this disclosure, the memory 1082 is implemented to store instructions 1084, data 1086, and other information of the electronic device 1002, and thus when configured as or part of a computer-readable storage medium, the memory 1082 does not include transitory propagating signals or carrier waves.

The electronic device 1002 may also include input/output ports 1090. The I/O ports 1090 enable data exchanges or interaction with other devices, networks, or users or between components of the device.

The electronic device 1002 may further include at least one signal processor (SP) 1092 (e.g., such as a digital signal processor (DSP)). The signal processor 1092 may function similar to the processor and may be capable of executing instructions and/or processing information in conjunction with the memory 1082.

For communication purposes, the electronic device 1002 also includes a modem 1094, a wireless transceiver 1096, and an antenna (not shown) as part of a filtenna. The wireless transceiver 1096 provides connectivity to respective networks and other electronic devices connected therewith using RF wireless signals and may include the transceiver circuit 900 of FIG. 9. The wireless transceiver 1096 may facilitate communication over any suitable type of wireless network, such as a wireless local area network (WLAN), a peer-to-peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN) (e.g., using ultra-wideband (UWB) technology).

### Example Aspects

In addition to the various aspects described above, specific combinations of aspects are within the scope of the disclosure, some of which are detailed below:

Aspect 1: An apparatus comprising: an antenna circuit configured to at least one of transmit or receive wireless signals over a target operating frequency band, the antenna circuit comprising: a radiating element configured to radiate electromagnetic waves, the radiating element having a first resonant frequency different from a center frequency of the target operating frequency band; and one or more acoustic resonators electrically coupled to the radiating element.

Aspect 2: The apparatus of Aspect 1, wherein the radiating element and the one or more acoustic resonators together form a combined filter circuit having a passband corresponding to the target operating frequency band.

Aspect 3: The apparatus of Aspect 1 or 2, wherein the one or more acoustic resonators are formed on a first die and the radiating element is formed on a second die different from the first die.

Aspect 4: The apparatus of Aspect 3, wherein the radiating element and the one or more acoustic resonators are packaged in a common package.

Aspect 5: The apparatus according to any of Aspects 1-4, wherein the radiating element and the one or more acoustic resonators are co-located together such that a conductive line coupling the radiating element to the one or more acoustic resonators forms a portion of the radiating element.

Aspect 6: The apparatus according to any of Aspects 1-5, wherein a series resonance of the one or more acoustic resonators is at the center frequency of the target operating frequency band.

Aspect 7: The apparatus according to any of Aspects 1-6, further comprising at least one of a transmitter or a receiver coupled to the antenna circuit, the transmitter being configured to transmit first wireless signals from the radiating element of the antenna circuit and the receiver being configured to receive second wireless signals with the radiating element of the antenna circuit.

Aspect 8: A filtenna comprising: an antenna configured to have a first resonance frequency associated with electromagnetic oscillations of the antenna; and one or more acoustic resonators coupled to the antenna, a first acoustic resonator in the one or more acoustic resonators configured to have a second resonance frequency associated with acoustic oscillations of the first acoustic resonator, wherein the filtenna is configured to have a filter transfer function based at least in part on the first resonance frequency of the antenna and the second resonance frequency of the first acoustic resonator.

Aspect 9: The filtenna of Aspect 8, wherein the filter transfer function is a bandpass filter function characterized by a center frequency and a bandwidth.

Aspect 10: The filtenna of Aspect 9, wherein at least one of the center frequency or the bandwidth is based at least in part on the first resonance frequency of the antenna and the second resonance frequency of the first acoustic resonator.

Aspect 11: The filtenna of Aspect 9 or 10, wherein the first resonance frequency of the antenna is offset from the center frequency of the bandpass filter function.

Aspect 12: The filtenna according to any of Aspects 8-11, wherein the first resonance frequency of the antenna is a series resonance frequency and wherein the first acoustic resonator is disposed adjacent to the antenna and is coupled in shunt with the antenna.

Aspect 13: The filtenna according to any of Aspects 8-11, wherein the first resonance frequency of the antenna is a parallel resonance frequency and wherein the first acoustic resonator is disposed adjacent to the antenna and is coupled in series with the antenna.

Aspect 14: The filtenna according to any of Aspects 8-13, wherein the one or more acoustic resonators comprise a plurality of acoustic resonators coupled to the antenna in a ladder-type configuration.

Aspect 15: The filtenna according to any of Aspects 8-14, wherein the first acoustic resonator is directly connected to a feedline of the antenna without a transmission line coupled between the feedline and the first acoustic resonator.

Aspect 16: A packaged assembly comprising the filtenna according to any of Aspects 8-15.

Aspect 17: The packaged assembly of Aspect 16, further comprising an active device coupled to the filtenna.

Aspect 18: A wireless device comprising the filtenna according to any of Aspects 8-17, the wireless device further comprising at least one of a transmitter or a receiver coupled to the filtenna, the transmitter being configured to transmit first wireless signals from the antenna of the filtenna and the receiver being configured to receive second wireless signals with the antenna of the filtenna.

Aspect 19: A method of processing a signal using an antenna circuit configured to at least one of transmit or receive wireless signals over a target operating frequency band, the method comprising: filtering the signal with a radiating element included in the antenna circuit, wherein the radiating element is configured to radiate electromagnetic waves and wherein the radiating element has a first resonant frequency different from a center frequency of the target operating frequency band; and filtering the signal with one or more acoustic resonators included in the antenna circuit and electrically coupled to the radiating element.

Aspect 20: The method of Aspect 19, wherein the radiating element and the one or more acoustic resonators together form a combined filter circuit having a passband corresponding to the target operating frequency band.

### Additional Considerations

The various operations of methods described above may be performed by any suitable means capable of performing the corresponding functions. The means may include various hardware and/or software component(s) and/or module(s).

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another-even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuit.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes, and variations may be made in the arrangement, operation, and details of the methods and apparatus described above without departing from the scope of the claims.

1. An apparatus comprising:
an antenna circuit configured to at least one of transmit or receive wireless signals over a target operating frequency band, the antenna circuit comprising:
a radiating element configured to radiate electromagnetic waves, the radiating element having a first resonant frequency different from a center frequency of the target operating frequency band; and
one or more acoustic resonators electrically coupled to the radiating element.

2. The apparatus of claim 1, wherein the radiating element and the one or more acoustic resonators together form a combined filter circuit having a passband corresponding to the target operating frequency band.

3. The apparatus of claim 1, wherein the one or more acoustic resonators are formed on a first die and the radiating element is formed on a second die different from the first die.

4. The apparatus of claim 3, wherein the radiating element and the one or more acoustic resonators are packaged in a common package.

5. The apparatus of claim 1, wherein the radiating element and the one or more acoustic resonators are co-located together such that a conductive line coupling the radiating element to the one or more acoustic resonators forms a portion of the radiating element.

6. The apparatus of claim 1, wherein a series resonance of the one or more acoustic resonators is at the center frequency of the target operating frequency band.

7. The apparatus of claim 1, further comprising at least one of a transmitter or a receiver coupled to the antenna circuit, the transmitter being configured to transmit first wireless signals from the radiating element of the antenna circuit and the receiver being configured to receive second wireless signals with the radiating element of the antenna circuit.

8. A filtenna comprising:
an antenna configured to have a first resonance frequency associated with electromagnetic oscillations of the antenna; and
one or more acoustic resonators coupled to the antenna, a first acoustic resonator in the one or more acoustic resonators configured to have a second resonance frequency associated with acoustic oscillations of the first acoustic resonator, wherein the filtenna is configured to have a filter transfer function based at least in part on the first resonance frequency of the antenna and the second resonance frequency of the first acoustic resonator.

9. The filtenna of claim 8, wherein the filter transfer function is a bandpass filter function characterized by a center frequency and a bandwidth.

10. The filtenna of claim 9, wherein at least one of the center frequency or the bandwidth is based at least in part on the first resonance frequency of the antenna and the second resonance frequency of the first acoustic resonator.

11. The filtenna of claim 9, wherein the first resonance frequency of the antenna is offset from the center frequency of the bandpass filter function.

12. The filtenna of claim 8, wherein the first resonance frequency of the antenna is a series resonance frequency and wherein the first acoustic resonator is disposed adjacent to the antenna and is coupled in shunt with the antenna.

13. The filtenna of claim 8, wherein the first resonance frequency of the antenna is a parallel resonance frequency and wherein the first acoustic resonator is disposed adjacent to the antenna and is coupled in series with the antenna.

14. The filtenna of claim 8, wherein the one or more acoustic resonators comprise a plurality of acoustic resonators coupled to the antenna in a ladder-type configuration.

15. The filtenna of claim 8, wherein the first acoustic resonator is directly connected to a feedline of the antenna without a transmission line coupled between the feedline and the first acoustic resonator.

16. A packaged assembly comprising the filtenna of claim 8.

17. The packaged assembly of claim 16, further comprising an active device coupled to the filtenna.

18. A wireless device comprising the filtenna of claim 8, the wireless device further comprising at least one of a transmitter or a receiver coupled to the filtenna, the transmitter being configured to transmit first wireless signals from the antenna of the filtenna and the receiver being configured to receive second wireless signals with the antenna of the filtenna.

19. A method of processing a signal using an antenna circuit configured to at least one of transmit or receive wireless signals over a target operating frequency band, the method comprising:
filtering the signal with a radiating element included in the antenna circuit, wherein the radiating element is configured to radiate electromagnetic waves and wherein the radiating element has a first resonant frequency different from a center frequency of the target operating frequency band; and
filtering the signal with one or more acoustic resonators included in the antenna circuit and electrically coupled to the radiating element.

20. The method of claim 19, wherein the radiating element and the one or more acoustic resonators together form a combined filter circuit having a passband corresponding to the target operating frequency band.
